(19) United States
(12) Patent Application Publication
(10) Pub. No.: US 2026/0182344 A1
(43) Pub. Date: Jun. 25, 2026

(54) INTEGRATED CIRCUIT INCLUDING BACK-SIDE WIRE LAYER

(71) Applicant: Samsung Electronics Co., Ltd., Suwon-si (KR)

(72) Inventors: Jisoo Park, Suwon-si (KR); Junghan Lee, Suwon-si (KR); Panjae Park, Suwon-si (KR); Byungsung Kim, Suwon-si (KR); Kwanyoung Chun, Suwon-si (KR)

(21) Appl. No.: 19/261,345

(22) Filed: Jul. 7, 2025

(30) Foreign Application Priority Data
Dec. 24, 2024 (KR) 10-2024-0196074

(51) Int. Cl. H01L 23/528; H01L 23/522; H10D 30/00; H10D 30/43; H10D 84/85

(52) U.S. Cl. CPC H10W 20/43; H10D 30/43; H10D 30/502; H10D 84/851; H10W 20/42; H10W 20/435

(57) ABSTRACT

An integrated circuit, enables power to flow stably in a cell boundary and includes a back-side wire layer capable of reducing coupling interference between devices, includes a back-side wire layer including back-side metal lines each extending in a first direction and spaced apart from each other in a second direction perpendicular to the first direction, a field effect transistor (FET) disposed above the back-side wire layer, and a front-side wire layer disposed above the FET and including front-side metal lines that extend in the first direction and are spaced apart from each other in the second direction, an n-number of front-side metal lines are arranged in a cell in the second direction at a first pitch, and an m-number of back-side metal lines are arranged in the cell in the second direction at a second pitch.

### CROSS-REFERENCE TO RELATED APPLICATION

This application is based on and claims priority under 35 U.S.C. § 119 to Korean Patent Application No. 10-2024-0196074, filed on Dec. 24, 2024, in the Korean Intellectual Property Office, the disclosure of which is incorporated by reference herein in its entirety.

### BACKGROUND

Recently, as scaling of integrated circuits has become more advanced, a back-side power delivery networks (BSPDN) has been employed. The BSPDN literally represents technology for applying a PDN to a back-side. Here, the network may represent a set of interconnections, and the interconnections may generally represent metal interconnections. Also, the network may be classified into a signal network and a power delivery network depending on usage. The signal network represents a set of interconnections used to exchange signals between transistors or with external devices. On the other hand, the power delivery network represents a set of interconnections for supplying power to operate transistors. According to the related art, power is transmitted through the front-side, but recently, power may also be transmitted through the back-side by using the BSPDN.

### SUMMARY

In general, the present disclosure is directed toward an integrated circuit that enables power to flow stably in a cell boundary and includes a back-side wire layer capable of reducing coupling interference between devices.

According to some implementations, the present disclosure is directed to an integrated circuit that includes a back-side wire layer including back-side metal lines each extending in a first direction and spaced apart from each other in a second direction perpendicular to the first direction, a field effect transistor (FET) disposed above the back-side wire layer, and a front-side wire layer disposed above the FET and including front-side metal lines that extend in the first direction and are spaced apart from each other in the second direction, n front-side metal lines are arranged in a cell in the second direction at a first pitch (where n is an integer greater than or equal to 1), and m back-side metal lines are arranged in the cell in the second direction at a second pitch (where m is an integer greater than or equal to 1).

According to some implementations, the present disclosure is directed to an integrated circuit that includes a back-side wire layer including back-side metal lines each extending in a first direction and spaced apart from each other in a second direction perpendicular to the first direction, a cell region disposed above the back-side wire layer and including active regions, extending in the first direction and spaced apart from each other in the second direction, and gate lines, extending in the second direction and spaced apart from each other in the first direction, and a front-side wire layer disposed above the cell region and including front-side metal lines that extend in the first direction and are spaced apart from each other in the second direction, wherein a first front-side power line and a second front-side power line among the front-side metal lines are aligned with cell boundaries (CBs) on both sides of a cell in the second direction in the cell region, a first back-side power line and a second back-side power line among the back-side metal lines are aligned with the CBs on both sides of the cell in the second direction, n front-side metal lines are arranged inside the cell in the second direction at a first pitch (where n is an integer greater than or equal to 1), and m back-side metal lines are arranged inside the cell in the second direction at a second pitch (where m is an integer greater than or equal to 1).

According to some implementations, the present disclosure is directed to an integrated circuit that includes a back-side wire layer including back-side metal lines each extending in a first direction and spaced apart from each other in a second direction perpendicular to the first direction, an FET disposed above the back-side wire layer, and a front-side wire layer disposed above the FET and including front-side metal lines that extend in the first direction and are spaced apart from each other in the second direction, wherein a first front-side power line and a second front-side power line among the front-side metal lines are aligned with CBs of a cell in the second direction, power is applied to the first front-side power line and the second front-side power line, a first back-side power line and a second back-side power line among the back-side metal lines are aligned with the CBs on both sides of the cell in the second direction, the power is applied to the first back-side power line and the second back-side power line, n front-side metal lines are arranged in the cell in the second direction at a first pitch (where n is an integer greater than or equal to 1), and m back-side metal lines are arranged in the cell in the second direction at a second pitch (where m is an integer greater than or equal to 1).

### BRIEF DESCRIPTION OF THE DRAWINGS

Example implementations will be more clearly understood from the following detailed explanation, taken in conjunction with the accompanying drawings.

FIGS. 1A and 1B are a layout and a cross-sectional view, respectively, of an example of an integrated circuit including a back-side wire layer according to some implementations.

FIG. 2 is a graph showing an example of a coupling effect between devices when power current is supplied or not supplied to an M1 metal line of a cell boundary according to some implementations.

FIGS. 3A and 3B are example layouts of an integrated circuit according to some implementations and an integrated circuit according to a comparison example, respectively, inside one cell.

FIGS. 4A and 4B are conceptual diagrams showing examples of vertical positional relationships between back-side wire layers and front-side wire layers in the integrated circuits of FIGS. 3A and 3B, respectively, according to some implementations.

FIGS. 5A to 5D show layouts of examples of various ratios between pitches of front-side metal lines of a front-side wire layer and pitches of back-side metal lines of a back-side wire layer inside one cell according to some implementations.

FIGS. 6A to 6D are perspective views showing example structures of various FETs that may be included in an integrated circuit according to some implementations.

### DETAILED DESCRIPTION

Hereinafter, example implementations will be explained in detail with reference to the accompanying drawings.

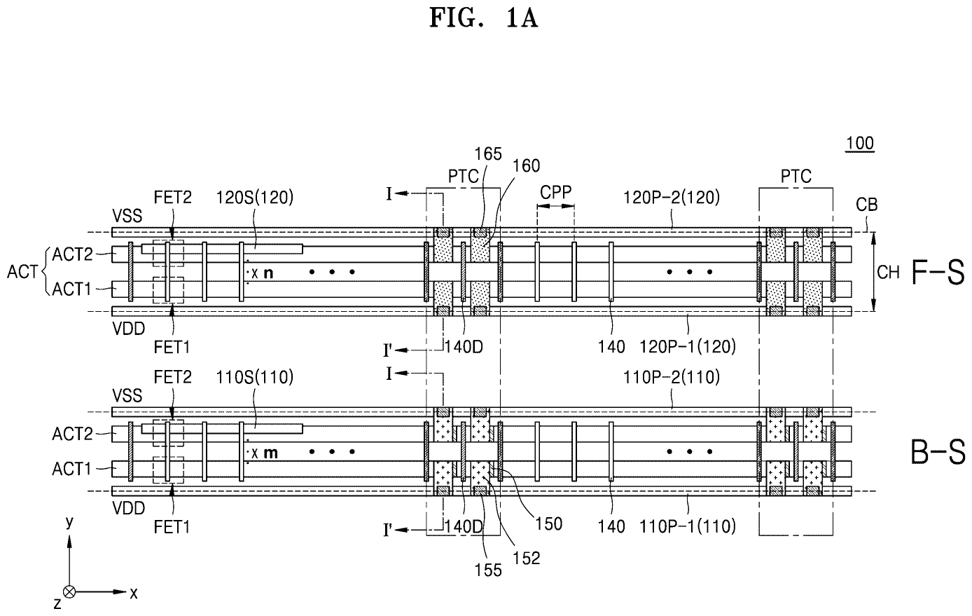

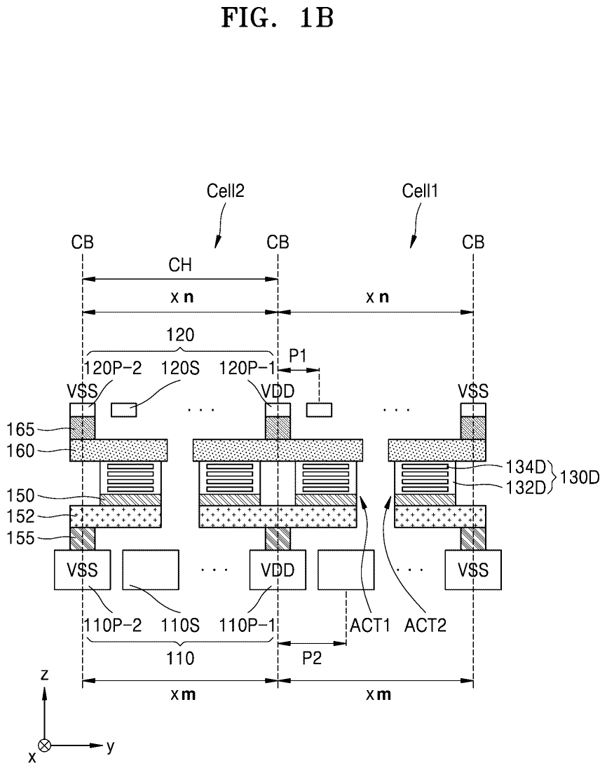

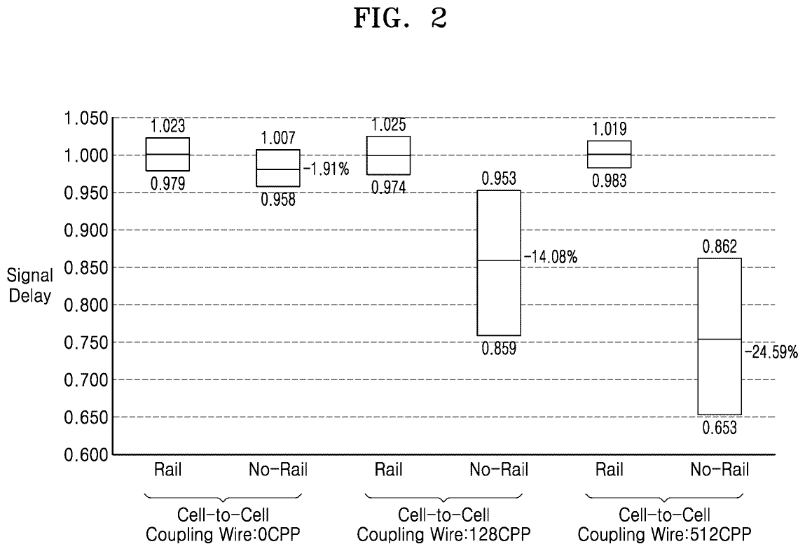

FIG. 1A is a layout of an example of an integrated circuit 100 including a back-side wire layer according to some implementations, and FIG. 1B is a cross-sectional view of the integrated circuit 100 taken along line I-I′ of FIG. 1A according to some implementations. FIG. 2 is a graph showing an example of a coupling effect between devices when power current is supplied or not supplied to an M1 metal line of a cell boundary according to some implementations.

In FIGS. 1A and 1B, the integrated circuit 100 may include a back-side wire layer 110, a field effect transistor (FET), and a front-side wire layer 120. Here, a back-side B-S may represent a lower side in a z direction, and a front-side F-S may represent an upper side in the z direction. For example, in FIG. 1B, the back-side wire layer 110, the FET, and the front-side wire layer 120 may be arranged in this order in the z direction. For reference, in FIG. 1A, the layout at the top corresponds to a plan view of the integrated circuit 100 when viewed from the front-side, and the layout at the bottom corresponds to a plan view of the integrated circuit 100 when viewed from the back-side. Also, FIG. IB corresponds to a cross-sectional view of the integrated circuit 100, in which two cells are cut in a y direction.

The back-side wire layer 110 may include a plurality of back-side metal lines extending in an x direction and spaced apart from each other in the y direction. The back-side metal lines may include a first back-side power line 110P-1, a second back-side power line 110P-2, and a back-side signal line 110S. The first back-side power line 110P-1 may provide the FET with first power VDD, for example, power of positive potential. The second back-side power line 110P-2 may be spaced apart from the first back-side power line 110P-1 in the y direction and provide the FET with second power VSS, for example, power of negative potential or ground potential. The first back-side power line 110P-1 and the second back-side power line 110P-2 may be connected to an active region ACT via a back-side contact 150 in a power tap cell PTC. The back-side signal line 110S may be located between the first back-side power line 110P-1 and the second back-side power line 110P-2 in the y direction. The back-side signal line 110S may be connected to the source/drain of the FET. Signals may be input to and output from the FET via the back-side signal line 110S. In some embodiments, the back-side signal line 110S may be omitted. In some embodiments, a plurality of back-side signal lines 110S may be arranged between the first back-side power line 110P-1 and the second back-side power line 110P-2.

In the integrated circuit 100, the back-side wire layer 110 may correspond to the uppermost metal wire layer among metal wire layers arranged in a multi-layer structure on the back-side of the integrated circuit 100. In other words, the back-side wire layer 110 may correspond to a metal line, which is closest to the FET on the back side, for example, a back-side M1 metal wire layer. Also, the first back-side power line 110P-1 and the second back-side power line 110P-2 of the back-side wire layer 110 may be respectively aligned with cell boundaries CB on both sides of one cell in the y direction. Also, the first back-side power line 110P-1 and the second back-side power line 110P-2 may be alternately arranged in the y direction.

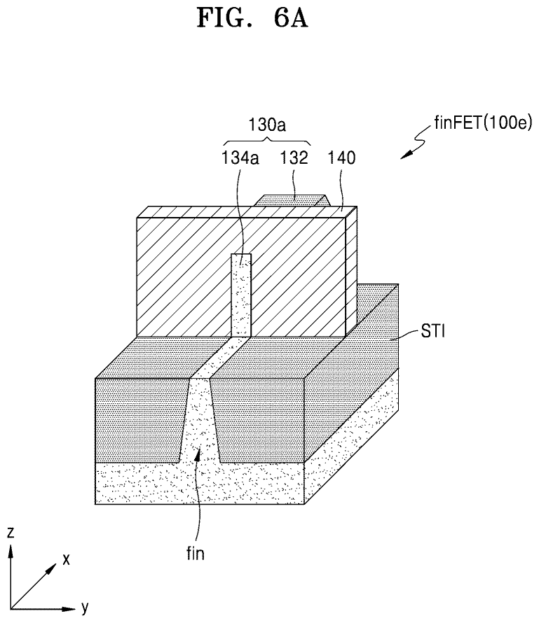

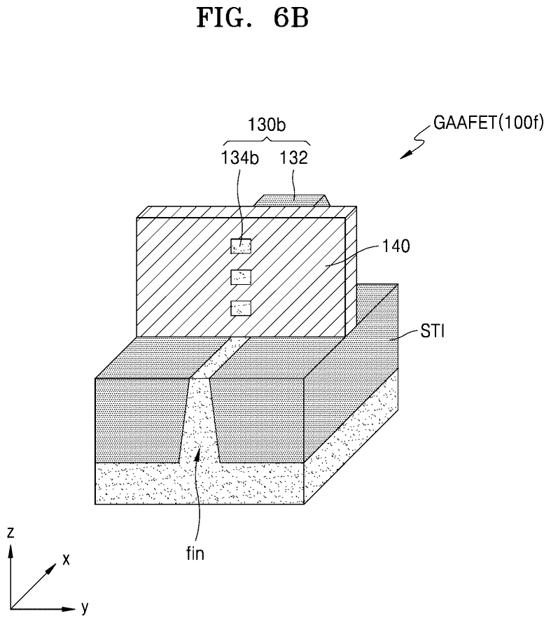

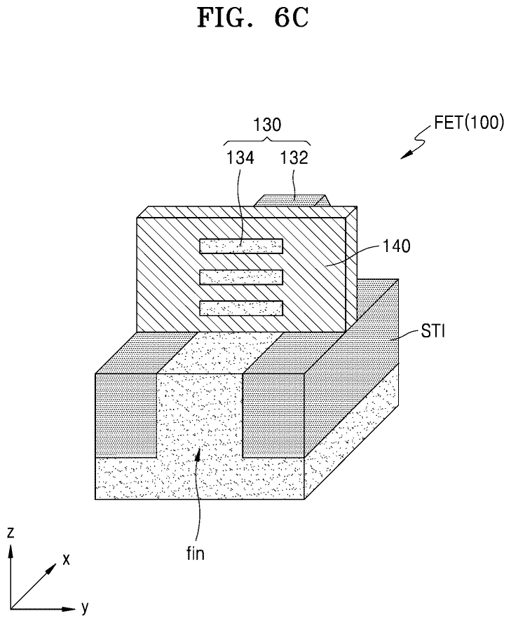

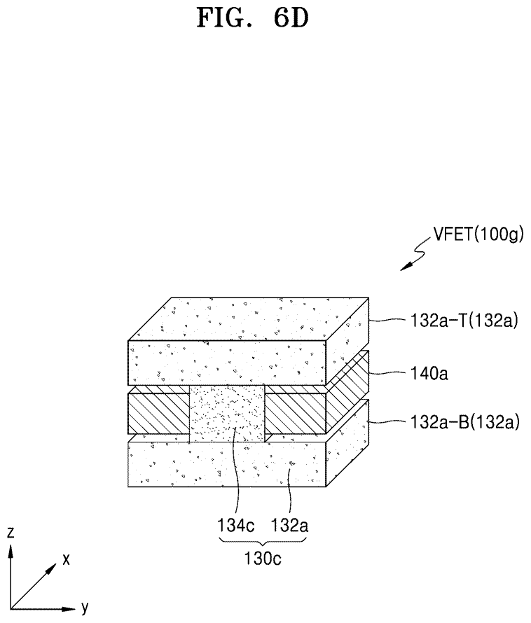

When the cell is described in more detail, a cell region may be located between the back-side wire layer 110 and the front-side wire layer 120 in the integrated circuit 100 according to some implementations. Also, a plurality of active regions ACT and gate lines 140 may be arranged in the cell region. The active regions ACT may each extend in the x direction and be spaced apart from each other in the y direction. The gate lines 140 may each extend in the y direction and be spaced apart from each other in the x direction. One cell may include two active regions ACT in the y direction, for example, a first active region ACT1 and a second active region ACT2. Also, one cell may include a source/drain 132 (see FIG. 6C) arranged on both sides with respect to one gate line 140 in the x direction.

Also, a cell height CH may represent the width of one cell in the y direction and correspond to the distance between the cell boundaries CB on both sides of the one cell in the y direction. Here, the cell boundary CB may be defined at the midpoint between two adjacent active regions ACT in two cells adjacent to each other in the y direction. For example, when a cell shown in FIG. 1A, i.e., a cell on the right side in FIG. 1B, is a first cell Cell1, and a cell below the first cell Cell1 in the y direction, i.e., a cell on the left side in FIG. 1B, is a second cell Cell2, the midpoint between the first active region ACT1 of the first cell Cell1 and the second active region ACT2 of the second cell Cell2 may correspond to the cell boundary CB on the lower side of the first cell Cell1. Also, when a cell located above the first cell Cell1 in the y direction is referred to as a third cell, the midpoint between the second active region ACT2 of the first cell Cell1 and the first active region ACT1 of the third cell may correspond to the cell boundary CB on the upper side of the first cell Cell1.

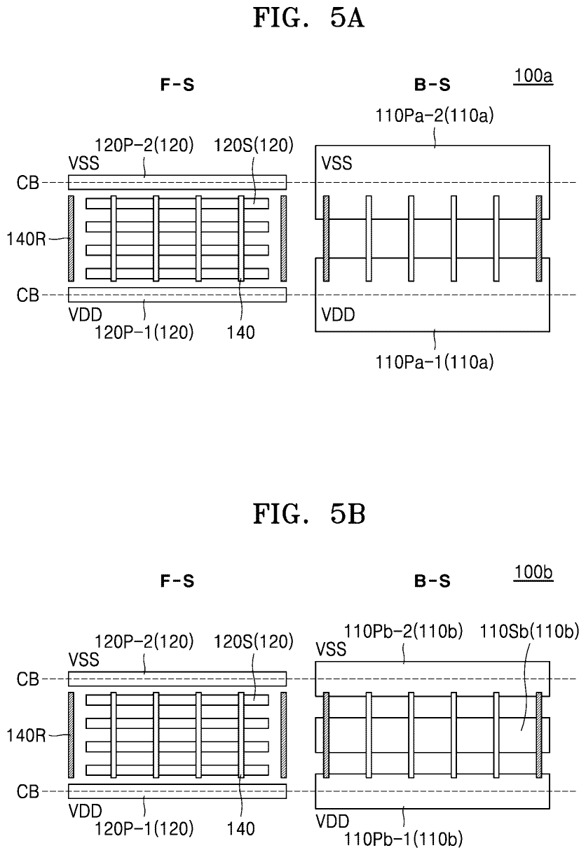

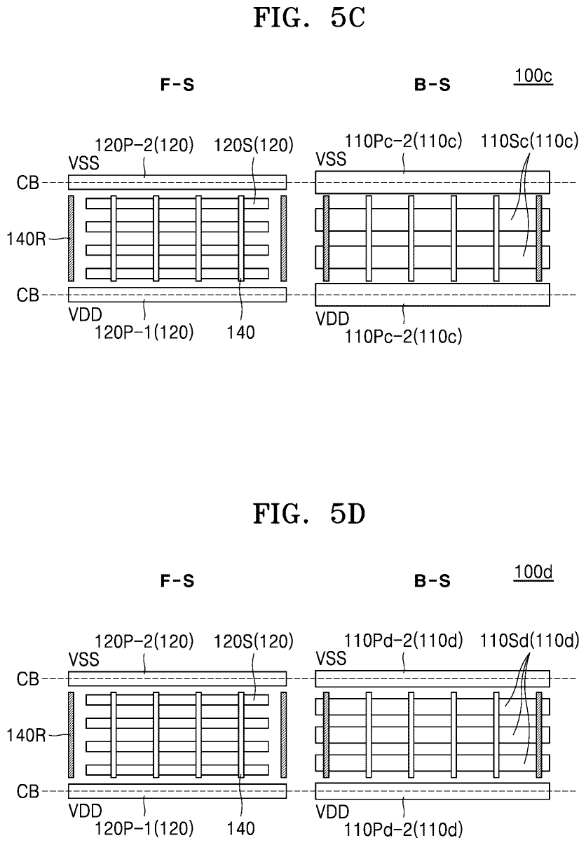

In FIGS. 1A and 1B, in the integrated circuit 100, the first back-side power line 110P-1 and the second back-side power line 110P-2 may be respectively aligned with the cell boundaries CB on both sides of one cell in the y direction. The arrangement configuration of the back-side wire layer 110 in the y direction is described in more detail with reference to FIGS. 5A and 5B.

The front-side wire layer 120 may include a plurality of front-side metal lines extending in an x direction and spaced apart from each other in the y direction. The front-side metal lines may include a first front-side power line 120P-1, a second front-side power line 120P-2, and a front-side signal line 120S. The first front-side power line 120P-1 may provide the FET with first power VDD, for example, power of positive potential. The second front-side power line 120P-2 may be spaced apart from the first front-side power line 120P-1 in the y direction and provide the FET with second power VSS, for example, power of negative potential or ground potential. The first front-side power line 120P-1 and the second front-side power line 120P-2 may be connected to the active region ACT via a contact 160 in the power tap cell PTC. The front-side signal line 120S may be located between the first front-side power line 120P-1 and the second front-side power line 120P-2 in the y direction. The front-side signal line 120S may be connected to the source/drain of the FET. Signals may be input to and output from the FET via the front-side signal line 120S. A plurality of front-side signal lines 120S may be spaced apart from each other in the y direction between the first front-side power line 120P-1 and the second front-side power line 120P-2.

In the integrated circuit 100, the front-side wire layer 120 may correspond to the lowermost metal wire layer among metal wire layers arranged in a multi-layer structure on the front-side of a substrate. In other words, the front-side wire layer 120 may correspond to a metal wire layer, which is closest to the FET on the front side, for example, an M1 metal wire layer. In addition, the first front-side power line 120P-1 and the second front-side power line 120P-2 of the front-side wire layer 120 may be respectively aligned with the cell boundaries CB on both sides of one cell in the y direction. Also, the first front-side power line 120P-1 and the second front-side power line 120P-2 may be alternately arranged in the y direction.

The FET may be located between the back-side wire layer 110 and the front-side wire layer 120 in the z direction. Two FETs may be arranged inside one cell. For example, a first FET FET1 including a first active region ACT1 and a second FET FET2 including a second active region ACT2 may be arranged inside one cell. In the integrated circuit 100 according to the embodiment, the first FET FET1 may include a p-channel metal-oxide semiconductor (PMOS) FET, and the second FET FET2 may include an n-channel metal-oxide semiconductor (NMOS) FET. However, in some implementations, the first FET FET1 may include an NMOS FET, and the second FET FET2 may include a PMOS FET. The first FET FET1 and the second FET FET2 may each include the gate line 140 and an active pattern 130 (see FIG. 6C). The active pattern 130 may have the active region ACT, and may include the source/drain 132 arranged on both sides of the gate line 140 in the x direction and a channel 134 (see FIG. 6C) located between the source and the drain. As illustrated in FIG. 1A, the first FET FET1 and the second FET FET2 may share the gate line 140.

The gate line 140 may extend in the y direction. The gate line 140 may surround, in various structures, the channel 134. For example, in the integrated circuit 100 according to the embodiment, the gate line 140 may surround the channel 134 in a gate all around (GAA) structure. However, the structure of the gate line 140 is not limited to the GAA structure.

The gate line 140 may include a gate dielectric layer and a gate electrode layer. The gate dielectric layer may include, for example, silicon oxide, silicon nitride, a high-k dielectric material, another dielectric material, and/or a combination thereof, and may include one or more dielectric materials. In some implementations, the gate dielectric layer may include an interfacial layer formed between channels and a dielectric material. In some implementations, the gate dielectric layer may be formed by using an atomic layer deposition (ALD) process to ensure a uniform thickness around each of the channels. However, a method of forming the gate dielectric layer is not limited to the ALD process.

The gate electrode layer may be formed on the gate dielectric layer to surround the channel 134. The gate electrode layer may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other conductive materials, and/or a combination thereof, and may include one or more conductive materials.

The active region ACT may include semiconductor materials, such as Si, SiGe, Ge, SiGeSn, GaAs, InSb, GaP, GaSb, InAlAs, InGaAs, GaSbP, GaAsSb, and InP. In the integrated circuit 100, the active region ACT may include Si or SiGe. As described above, the plurality of active regions ACT may extend in the x direction and be spaced apart from each other in the y direction. The active region ACT inside one cell may include the first active region ACT1 in a lower region and the second active region ACT2 in an upper region in the y direction. The active pattern 130 of the first active region ACT1 may form the source/drain 132 and the channel 134 of the first FET FET1, and the active pattern 130 of the second active region ACT2 may form the source/drain 132 and the channel 134 of the second FET FET2. The first active region ACT1 and the second active region ACT2 may be electrically isolated from each other by a dielectric layer.

Also, the channels 134 of the first FET FET1 and the second FET FET2 may each have a multi-bridge channel (MBC) structure, and four surfaces of the channels 134 may be surrounded by the gate line 140. Here, the four surfaces thereof may include two surfaces in the y direction and two surfaces in the z direction. In some embodiments, the channels 134 of the first FET FET1 and the second FET FET2 may each include at least two nano-sheets. However, in other embodiments, at least one of the channels 134 of the first FET FET1 and the second FET FET2 may include only one nano-sheet. In the integrated circuit 100, the structure of the channels 134 of the first FET FET1 and the second FET FET2 is not limited to the MBC structure. The FETs including gate lines 140 and channels 134 in other structures are described in more detail with reference to FIGS. 6A to 6D.

The contact 160 and the back-side contact 150 may be arranged in the power tap cell PTC as described above. The first front-side power line 120P-1 may be connected to the first back-side power line 110P-1 via the contact 160, the first active region ACT1, and the back-side contact 150. Also, the second front-side power line 120P-2 may be connected to the second back-side power line 110P-2 via the contact 160, the second active region ACT2, and the back-side contact 150. Power tap cells PTC may be arranged one per every several tens to several hundreds of contacted poly pitches CPP in the x direction. For example, in the integrated circuit 100 according to the embodiment, one power tap cell PTC may be placed, for example, at every about 60 contacted poly pitches CPP. However, the arrangement interval of the power tap cells PTC is not limited to the numerical value described above.

Here, the contacted poly pitch CPP may represent a pitch between the gate lines 140 in the x direction. As shown in FIG. 1A, in the integrated circuit 100, the size of the power tap cell PTC is set to the size of two contacted poly pitches CPP in the x direction and one cell height CH. However, the size of the power tap cell PTC is not limited thereto. For example, the size of the power tap cell PTC may be set to one or more contacted poly pitches CPP in the x direction and one or more cell heights CH in the y direction.

For reference, the active region ACT in the power tap cell PTC may include a dummy active pattern 130D. Also, the dummy active pattern 130D may include a dummy source/drain 132D and a dummy channel 134D. A dummy gate line 140D may be located in the power tap cell PTC, and the dummy gate line 140D may have a single diffusion break (SDB) structure. Accordingly, in the power tap cell PTC, the dummy active pattern 130D may not operate as a component of the FET. However, the dummy source/drain 132D of the dummy active pattern 130D may include a path for power between the first front-side power line 120P-1 and the first back-side power line 110P-1 and between the second front-side power line 120P-2 and the second back-side power line 110P-2.

For reference, the SDB may have substantially the same width as the gate line 140 in the x direction. For example, the SDB may have a structure in which an insulating layer having substantially the same width as a gate extends into a semiconductor substrate and separates an active region ACT. Unlike double diffusion break (DDB), the SDB does not have a separate dummy gate, and an upper portion of the insulating layer that forms the SDB corresponding to the gate may protrude from a substrate.

On the other hand, the DDB has a different separation structure of the active region ACT than the SDB, and may be formed across two gates. For example, the DDB may be formed by arranging an insulating layer in a buried structure below two adjacent gates in the x direction. Accordingly, the DDB has a pitch between gates in the x direction, for example, the width corresponding to the contacted poly pitch CPP, and in the DDB, two upper gates may correspond to dummy gates.

Also, considering the size of a cell, two cells including the DDB may be larger, by one contacted poly pitch CPP in the x direction, than two cells including the SDB. Therefore, the cells including the SDB may be advantageous in terms of size. Also, an insulating layer forming the DDB and the SDB may include a compressive stress material and/or a tensile stress material. Here, the compressive stress material includes a material capable of applying compressive stress to an active region, and the tensile stress material includes a material capable of applying tensile stress to the active region. For example, the insulating layer of the SDB may include silicon nitride, and the insulating layer of the DDB may include an oxide such as tetraethyl orthosilicate (TEOS). However, the materials of the insulating layers of the DDB and the SDB are not limited to the materials described above.

In the power tap cell PTC of the integrated circuit 100, the connection relationship to the dummy active pattern 130D of the back-side wire layer 110 and the front-side wire layer 120, for example, the dummy source/drain 132D, is as follows. The first back-side power line 110P-1 and the second back-side power line 110P-2 of the back-side wire layer 110 may be connected to the dummy source/drain 132D via the back-side contact 150, a metal plate via 152, and a back-side via 155. As shown in FIG. 1B, the back-side contact 150 may be in contact with the dummy source/drain 132D corresponding thereto, and the metal plate via 152 may be in common contact with two back-side contacts 150 that are in contact with two dummy sources/drains 132D adjacent to each other in the y direction. Also, the first front-side power line 120P-1 and the second front-side power line 120P-2 of the front-side wire layer 120 may be connected to the dummy source/drain 132D via the contact 160 and a via 165. As shown in FIG. 1B, the contact 160 may be in common contact with two dummy sources/drains 132D in the y direction.

For reference, in the integrated circuit 100, a cell may correspond to, for example, a standard cell, and accordingly, a basic layout may be used when designing the integrated circuit. When the standard cell is described in more detail, as semiconductor devices have become highly integrated in recent years, a lot of time and money are spent on designing a layout of integrated circuits, especially a device region. Accordingly, to reduce those described above, a standard cell-based layout design technique may be used. The standard cell-based layout design technique may reduce the time required for layout design, by designing logic devices, such as OR gates and AND gates, that are used repeatedly as standard cells in advance, storing the logic devices in a computer system, and placing and wiring the logic devices at necessary locations when designing the layout.

For example, the standard cell may include a basic cell, such as an AND, an OR, a NOR, an inverter, a NAND, and a NOR, a complex cell, such as an OR/AND/INVERTER (OAI) and an AND/OR/INVERTER (AOI), and a storage element, such as a simple master-slave flip-flop and a latch.

A standard cell method includes a method of preparing logic circuit blocks having a plurality of functions, i.e., cells, in advance and combining these cells arbitrarily, thereby designing a dedicated large-scale integrated circuit (LSI) customized to the needs of a customer or a user. The cells may be designed and verified in advance and then registered in a computer. The logical design, arrangement, and interconnection may be performed by combining the registered cells using computer-aided design (CAD).

Specifically, in the case of designing/manufacturing the LSI, when a certain number of standardized logic circuit blocks, i.e., standard cells, are already stored in a library, the standard cell that satisfies the current design purpose may be taken out of the library and placed on a chip as a plurality of cells. The entire circuit may be designed by performing optimal interconnection in an interconnection space between cells to achieve the shortest interconnection length. As the types of cells stored in the library are more abundant, the design becomes more flexible, and thus, the possibility of optimal chip design increases.

In the integrated circuit 100, n front-side metal lines of the front-side wire layer 120 may be arranged inside one cell at a first pitch P1 in the y direction (where n is an integer greater than or equal to 1). Also, m back-side metal lines of the back-side wire layer 110 may be arranged inside one cell at a second pitch P2 (where m is an integer greater than or equal to 1). Accordingly, the front-side metal lines of the front-side wire layer 120 and the back-side metal lines of the back-side wire layer 110 may have a pitch of an integer ratio in the y direction. Specifically, when the cell height CH is 1, n is 5, and m is 3, the first pitch P1 between the front-side metal lines in the front-side wire layer 120 is ⅕, and the second pitch P2 between the back-side metal lines in the back-side wire layer 110 is ⅓. Accordingly, the first pitch P1:the second pitch P2 may be 3:5. Also, instead of the pitch, the ratio may be defined by the number of front-side metal lines of the front-side wire layer 120 and the number of back-side metal lines of the back-side wire layer 110 arranged inside one cell. In this case, the number (n) of front-side metal lines:the number (m) of back-side metal lines may be 5:3. Here, m may be less than or equal to n. However, the relationship in sizes between m and n is not limited to that described above.

In the integrated circuit 100, the first front-side power line 120P-1 and the second front-side power line 120P-2 of the front-side wire layer 120 may be respectively aligned with the cell boundaries CB on both sides of one cell in the y direction. In addition, the first back-side power line 110P-1 and the second back-side power line 110P-2 of the back-side wire layer 110 may be respectively aligned with cell boundaries CB on both sides of one cell in the y direction.

In the front-side wire layer 120, the first front-side power line 120P-1 and the second front-side power line 120P-2 may each be located in common in two cells, and half of each may be allocated to one cell. Accordingly, n−1 front-side signal lines 120S may be arranged inside one cell. Specifically, for example, when n is 5, the first front-side power line 120P-1 and the second front-side power line 120P-2 are aligned with the cell boundaries CB in one cell in the y direction, and four front-side signal lines 120S may be arranged between the first front-side power line 120P-1 and the second front-side power line 120P-2. The same concept may also be applied to the back-side wire layer 110. The structures of the front-side wire layer 120 and the back-side wire layer 110, which are arranged at other ratios of n and m, are described in more detail with reference to FIGS. 5A to 5D.

In the integrated circuit 100, the first back-side power line 110P-1, the second back-side power line 110P-2, the first front-side power line 120P-1, and the second front-side power line 120P-2 (hereinafter, simply referred to as the power lines 110P-1, 110P-2, 120P-1, and 120P-2) of the front-side wire layer 120 and the back-side wire layer 110 are aligned with the cell boundaries CB. This allows power current to flow stably in the cell boundaries CB via the power lines 110P-1, 110P-2, 120P-1, and 120P-2, thereby preventing coupling interference between adjacent devices. To be more specific, in the case of the front-side and back-side M1 metal lines, when there is no power current in the cell boundary CB, the coupling interference between adjacent devices may lead to the devices being unusable.

FIG. 2 shows an example of the coupling effect. The x-axis represents the cell boundaries CB at intervals of 0, 128, and 512 contacted poly pitches CPP, and shows a signal delay when power current is supplied to the cell boundaries (Rail) and when not supplied (No-Rail). The y-axis represents the signal delay, and the unit thereof is normalized. As can be seen from the graph, when the cell boundary CB is not supplied with power current (No-Rail), a large signal delay occurs, which increases as the interval of the contacted poly pitch CPP increases.

In the integrated circuit 100, the power lines 110P-1, 110P-2, 120P-1, and 120P-2 of the front-side wire layer 120 and the back-side wire layer 110 are aligned with the cell boundaries CB and the power current is allowed to flow, thereby preventing coupling interference between adjacent devices. In addition, the front-side metal lines of the front-side wire layer 120 and the back-side metal lines of the back-side wire layer 110 may be arranged inside the cell at specific integer ratios, thereby enabling various operations of the back-side signal lines 110S of the back-side wire layer 110.

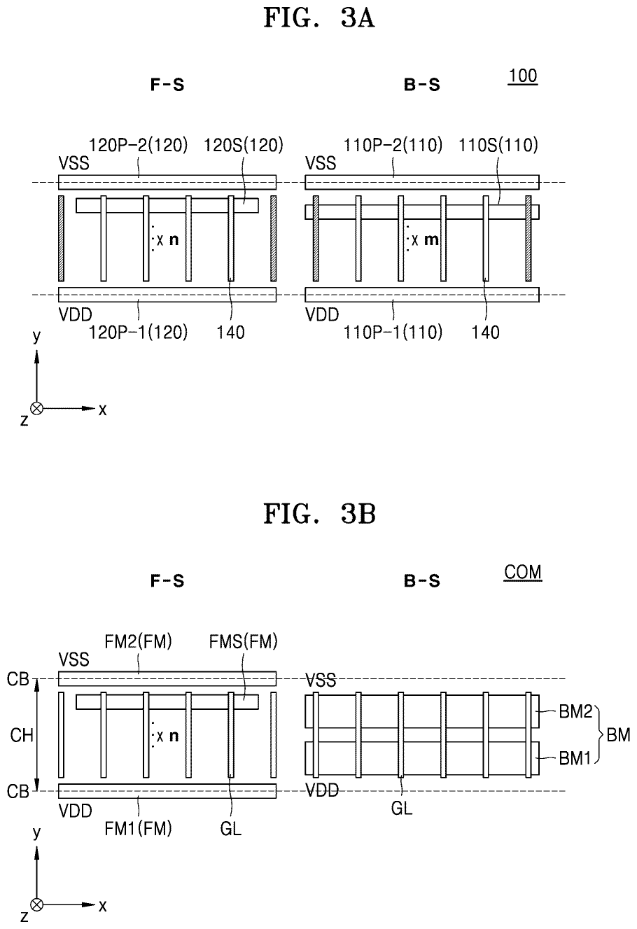

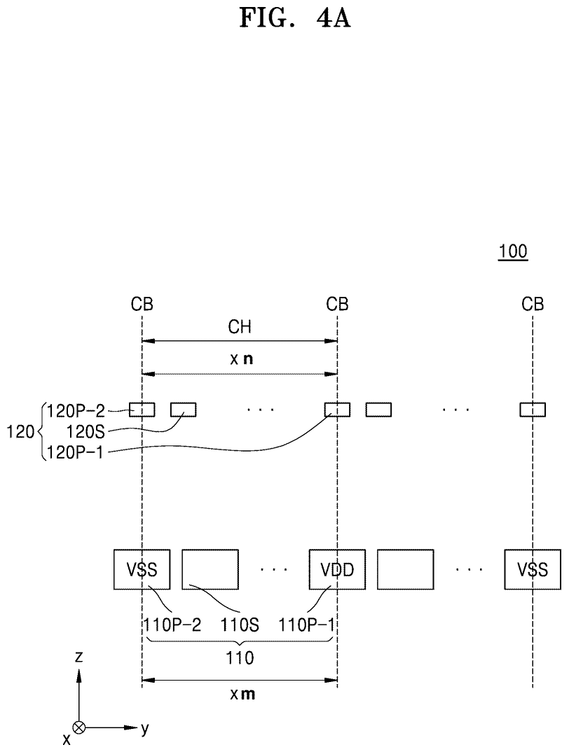

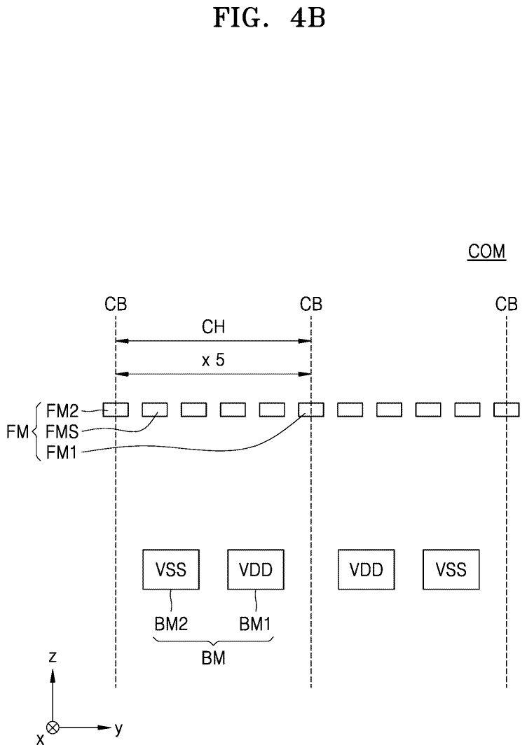

FIGS. 3A and 3B respectively show example layouts for the integrated circuit 100 according to some implementations and an integrated circuit COM according to a comparative example inside one cell, and FIGS. 4A and 4B are conceptual diagrams showing examples of vertical positional relationship between back-side wire layers and front-side wire layers in the integrated circuits 100 and COM of FIGS. 3A and 3B, respectively. A description is given below with reference to FIGS. 1A and 1B together, and descriptions already given with reference to FIGS. 1A to 3D are simplified or omitted.

In FIGS. 3A and 4A, in the integrated circuit 100, n front-side metal lines of the front-side wire layer 120 may be arranged inside one cell in the y direction, and m back-side metal lines of the back-side wire layer 110 may be arranged. In addition, the first front-side power line 120P-1 and the second front-side power line 120P-2 of the front-side wire layer 120 may be aligned with the cell boundaries CB on both sides in the y direction, and the first back-side power line 110P-1 and the second back-side power line 110P-2 of the back-side wire layer 110 may be aligned with the cell boundaries CB on both sides in the y direction. Accordingly, the connections between the corresponding power lines 110P-1, 110P-2, 120P-1, and 120P-2 may be easily made in the power tap cell PTC. In addition, as the power lines 110P-1, 110P-2, 120P-1, and 120P-2 are aligned with the cell boundaries CB, power current may flow in the cell boundaries CB through the power lines 110P-1, 110P-2, 120P-1, and 120P-2. Accordingly, the effect of preventing coupling interference may be maximized.

In FIGS. 3B and 4B, in the integrated circuit COM according to the comparative example, the set number of, for example, five front-side metal lines of a front-side wire layer FM may be arranged in a cell in the y direction, and two back-side metal lines of a back-side wire layer BM may be arranged. Also, the first front-side power line FM1 and the second front-side power line FM2 of the front-side wire layer FM may be aligned with cell boundaries CB on both sides in the y direction. However, as can be seen in FIGS. 3B and 4B, a first back-side power line BM1 and a second back-side power line BM2 of the back-side wire layer BM are not aligned with the cell boundaries CB. Accordingly, in the power tap cells PTC, connections between the corresponding power lines 110P-1, 110P-2, 120P-1, and 120P-2 are not easily established, and additional contacts or vias may be required. In addition, the first and second back-side power lines BM1 and BM2 are not aligned with the cell boundaries CB, which may degrade the effect of preventing coupling interference. Furthermore, the back-side wire layer BM may not include the back-side signal line or include only one back-side signal line, which may prevent the use of the back-side signal line or limit the use of the back-side signal line.

FIGS. 5A to 5D show layouts showing various example ratios between pitches of front-side metal lines of a front-side wire layer and pitches of back-side metal lines of a back-side wire layer inside one cell according to some implementations. A description is given below with reference to FIGS. 1A and 1B together, and descriptions already given with reference to FIGS. 1A to 4B are simplified or omitted.

In FIG. 5A, an integrated circuit 100a is shown where the ratio of the number of front-side metal lines of the front-side wire layer 120 and the number of back-side metal lines of a back-side wire layer 110a inside a cell in the y direction is 5:1. Accordingly, five front-side metal lines of the front-side wire layer 120 may be arranged inside one cell in the y direction, and one back-side metal line of the back-side wire layer 110a may be arranged inside one cell in the y direction. Also, the first front-side power line 120P-1 and the second front-side power line 120P-2 of the front-side wire layer 120 may be aligned with the cell boundaries CB on both sides in the y direction, and a first back-side power line 110Pa-1 and a second back-side power line 110Pa-2 of the back-side wire layer 110a may be aligned with the cell boundaries CB on both sides in the y direction. In this case, the back-side wire layer 110a may not include a back-side signal line.

In FIG. 5B, an integrated circuit 100b is shown where the ratio of the number of front-side metal lines of the front-side wire layer 120 and the number of back-side metal lines of a back-side wire layer 110b inside a cell in the y direction is 5:2. Accordingly, five front-side metal lines of the front-side wire layer 120 may be arranged inside one cell in the y direction, and two back-side metal lines of the back-side wire layer 110b may be arranged inside one cell in the y direction. Also, the first front-side power line 120P-1 and the second front-side power line 120P-2 of the front-side wire layer 120 may be aligned with the cell boundaries CB on both sides in the y direction, and a first back-side power line 110Pb-1 and a second back-side power line 110Pb-2 of the back-side wire layer 110b may be aligned with the cell boundaries CB on both sides in the y direction. In this case, the back-side wire layer 110b may include one back-side signal line 110Sb.

In FIG. 5C, an integrated circuit 100c is shown where the ratio of the number of front-side metal lines of the front-side wire layer 120 and the number of back-side metal lines of a back-side wire layer 110c inside a cell in the y direction is 5:3. Accordingly, five front-side metal lines of the front-side wire layer 120 may be arranged inside one cell in the y direction, and three back-side metal lines of the back-side wire layer 110c may be arranged inside one cell in the y direction. Also, the first front-side power line 120P-1 and the second front-side power line 120P-2 of the front-side wire layer 120 may be aligned with the cell boundaries CB on both sides in the y direction, and a first back-side power line 110Pc-1 and a second back-side power line 110Pc-2 of the back-side wire layer 110c may be aligned with the cell boundaries CB on both sides in the y direction. In this case, the back-side wire layer 110c may include two back-side signal lines 110Sc.

In FIG. 5D, an integrated circuit 100d is shown where the ratio of the number of front-side metal lines of the front-side wire layer 120 and the number of back-side metal lines of a back-side wire layer 110d inside a cell in the y direction is 5:4. Accordingly, five front-side metal lines of the front-side wire layer 120 may be arranged inside one cell in the y direction, and four back-side metal lines of the back-side wire layer 110d may be arranged inside one cell in the y direction. Also, the first front-side power line 120P-1 and the second front-side power line 120P-2 of the front-side wire layer 120 may be aligned with the cell boundaries CB on both sides in the y direction, and a first back-side power line 110Pd-1 and a second back-side power line 110Pd-2 of the back-side wire layer 110d may be aligned with the cell boundaries CB on both sides in the y direction. In this case, the back-side wire layer 110c may include three back-side signal lines 110Sd.

FIGS. 6A to 6D are perspective views showing example structures of various FETs that may be included in an integrated circuit according to some implementations. For convenience of illustration, FIGS. 6A to 6C show a state in which one of two source/drain regions has been removed, and FIG. 6D shows a cross-section of a vertical-FET (VFET) taken along a plane that passes through a channel of the VFET and is perpendicular to the x direction. A description is given below with reference to FIGS. 1A and 1B together, and descriptions already given with reference to FIGS. 1A to 5D are simplified or omitted.

In FIG. 6A, an integrated circuit 100e may include, for example, a fin-type field effect transistor (finFET). The finFET may be located between the back-side wire layer 110 and the front-side wire layer 120, as shown in the integrated circuit 100 of FIG. 1A. When the finFET is described in more detail, the finFET may be formed by an active pattern 130a having a fin shape extending in the x direction between shallow trench isolations STI and the gate line 140 extending in the y direction. The active pattern 130a may include the source/drain 132 and a channel 134a. The source/drain 132 may be formed on both sides of the gate line 140, and the source and the drain may be spaced apart from each other in the x direction. An insulating layer may be formed between the channel 134a and the gate line 140. In some embodiments, a finFET may be formed by a plurality of active patterns 130a spaced apart from each other in the y direction and the gate line 140.

In FIG. 6B, an integrated circuit 100f may include, for example, a gate-all-around field effect transistor (GAAFET). The GAAFET may be located between the back-side wire layer 110 and the front-side wire layer 120, as shown in the integrated circuit 100 of FIG. 1A. The GAAFET may be formed by an active pattern 130b extending in the x direction and the gate line 140 extending in the y direction. The active pattern 130b may include the source/drain 132 and a channel 134b. The channel 134b may include, for example, nano-wires spaced apart from each other in the z direction. The source/drain 132 may be formed on both sides of the gate line 140, and thus, the source and the drain may be spaced apart from each other in the x direction. An insulating layer may be formed between the channel 134b and the gate line 140. FIG. 6B shows that the GAAFET includes three nano-wires, but the number of nano-wires in the GAAFET is not limited to three.

In FIG. 6C, the integrated circuit 100 may include, for example, a multi-bridge channel field effect transistor (MBCFET). The MBCFET may correspond to the FET of the integrated circuit 100 in FIG. 1A, and accordingly, the MBCFET may be disposed between the back-side wire layer 110 and the front-side wire layer 120. The MBCFET may be formed by the active pattern 130 extending in the x direction and the gate line 140 extending in the y direction. The active pattern 130 may include the source/drain 132 and the channel 134. The channel 134 may include, for example, nano-sheets spaced apart from each other in the z direction. The source/drain 132 may be formed on both sides of the gate line 140, and thus, the source and the drain may be spaced apart from each other in the x direction. An insulating layer may be formed between the channel 134 and the gate line 140. FIG. 6C shows that the MBCFET includes three nano-sheets, but the number of nano-sheets in the MBCFET is not limited to three.

In FIG. 6D, an integrated circuit 100g may include, for example, a VFET. The VFET may be located between the back-side wire layer 110 and the front-side wire layer 120, as shown in the integrated circuit 100 of FIG. 1A. The VFET may be formed by an active pattern 130c and a gate line 140a. Specifically, the VFET may include a top source/drain 132a-T and a bottom source/drain 132a-B, which are spaced apart from each other in the z direction with a channel 134c therebetween. The VFET may include the gate line 140a that surrounds a channel 134c between the top source/drain 132a-T and the bottom source/drain 132a-B. An insulating layer may be formed between the channel 134c and the gate line 140a.

So far, the structures of various FETs have been described. However, the integrated circuit according to the embodiment is not limited to the structures described above. For example, the integrated circuit according to the embodiment may include a ForkFET in which a dielectric wall isolates nano-sheets for a P-type transistor and nano-sheets for an N-type transistor, thereby forming a structure in which the N-type transistor is close to the P-type transistor. In addition, the integrated circuit according to the embodiment may include FETs, such as a complementary-FET (CFET), a negative capacitance-CFET (NC-CFET), and a carbon nanotube-FET (CNT-FET), and may further include a bipolar junction transistor.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit comprising:
a back-side wire layer comprising back-side metal lines extending in a first direction and spaced apart from each other in a second direction perpendicular to the first direction;
a field effect transistor above the back-side wire layer along a third direction; and
a front-side wire layer above the field effect transistor (FET) along the third direction, the front-side wiring layer comprising front-side metal lines extending in the first direction and spaced apart from each other in the second direction,
wherein n front-side metal lines are arranged in at least one cell in the second direction at a first pitch, wherein n is an integer greater than or equal to 1, and
wherein m back-side metal lines are arranged in the at least one cell in the second direction at a second pitch, wherein m is an integer greater than or equal to 1.

2. The integrated circuit of claim 1, comprising active regions extending in the first direction and spaced apart from each other in the second direction,
wherein the integrated circuit comprises a first cell,
wherein the first cell comprises two active regions spaced part in the second direction,
wherein the first cell comprises a first cell boundary at a first side of the first cell and comprises a second cell boundary at a second side of the first cell,
wherein the first cell boundary and the second cell boundary are spaced apart from one another along the second direction,
wherein a first front-side power line and a second front-side power line among the front-side metal lines are aligned with the first cell boundary and the second cell boundary, respectively, and
wherein a first back-side power line and a second back-side power line among the back-side metal lines are aligned with the first cell boundary and the second cell boundary, respectively.

3. The integrated circuit of claim 2,
wherein the first front-side power line is configured to receive first power, and the second front-side power line is configured to receive second power that is different from the first power, and
wherein the first back-side power line is configured to receive the first power, and the second back-side power line is configured to receive the second power.

4. The integrated circuit of claim 2, comprising a power tap cell, wherein the power tap cell comprises:
a contact configured to connect the first front-side power line and the second front-side power line to the two active regions of the first cell; and
a back-side contact configured to connect the first back-side power line and the second back-side power line to the two active regions of the first cell.

5. The integrated circuit of claim 4, comprising gate lines extending in the second direction and arranged in the first direction at a third pitch,
wherein the power tap cell has a width of one cell or more in the first direction and a width of the third pitch or more in the second direction.

6. The integrated circuit of claim 4,
wherein the contact is connected to the first front-side power line or the second front-side power line through a via, and
wherein the back-side contact is connected to the first back-side power line or the second back-side power line through a back-side via.

7. The integrated circuit of claim 6,
wherein the first front-side power line or the second front-side power line is located between the first cell and a second cell adjacent to the first cell in the second direction,
wherein the second cell comprises two additional active regions spaced part from each other in the second direction, and
wherein the contact is connected in common to the active regions of the first cell and to the additional active regions of the second cell.

8. The integrated circuit of claim 2,
wherein the FET comprises a gate line, a source, and a drain of a first active region on both sides of the gate line in the first direction, and a channel located between the source and the drain,
wherein the front-side wire layer comprises a metal wire layer closest to the FET on a front-side of the integrated circuit, and
wherein the back-side wire layer comprises a metal wire layer closest to the FET on a back-side of the integrated circuit.

9. The integrated circuit of claim 8,
wherein the channel comprises a multi-bridge channel structure, and
wherein the gate line comprises a gate all around structure.

10. The integrated circuit of claim 2, wherein a midpoint between two adjacent active regions in two cells adjacent to each other in the second direction is defined as a cell boundary.

11. The integrated circuit of claim 2, wherein a width of the first cell in the second direction is defined as a first width,
the number n of the front-side metal lines is based on the first width or the first pitch,
the number m of the back-side metal lines is based on the first width or the second pitch, and
the number n of the front-side metal lines is greater than or equal to the number m of the back-side metal lines.

12. An integrated circuit comprising:
a back-side wire layer comprising back-side metal lines extending in a first direction and spaced apart from each other in a second direction perpendicular to the first direction;
a cell region above the back-side wire layer and comprising
active regions, the active regions extending in the first direction and spaced apart from each other in the second direction, and
gate lines extending in the second direction and spaced apart from each other in the first direction; and
a front-side wire layer above the cell region and comprising front-side metal lines extending in the first direction, wherein the front-side metal lines are spaced apart from each other in the second direction,
wherein a first front-side power line and a second front-side power line of the front-side metal lines are aligned with cell boundaries on a first side and a second side, respectively, of a first cell in the cell region, wherein the first side and the second side are spaced apart in the second direction,
wherein a first back-side power line and a second back-side power line of the back-side metal lines are aligned with the cell boundaries on the first side and the second side, respectively, of the first cell,
wherein n front-side metal lines are arranged inside the first cell in the second direction at a first pitch, wherein n is an integer greater than or equal to 1, and
wherein m back-side metal lines are arranged inside the first cell in the second direction at a second pitch, wherein m is an integer greater than or equal to 1.

13. The integrated circuit of claim 12, comprising a power tap cell, wherein the power tap cell comprises a contact configured to connect the first front-side power line and the second front-side power line to the active regions and a back-side contact configured to connect the first back-side power line and the second back-side power line to the active regions,
wherein the gate lines are arranged in the first direction at a third pitch, and
wherein the power tap cell has a width equal to a width of one or more cells in the first direction and a length equal to a length of the third pitch or greater in the second direction.

14. The integrated circuit of claim 13,
wherein the first front-side power line or the second front-side power line is between two cells that are adjacent to each other in the second direction, and
wherein the contact is connected in common to the active regions of the two cells that are adjacent to each other.

15. The integrated circuit of claim 12,
wherein a first gate line, a source, a drain, and a channel located between the source and the drain form a field effect transistor in the cell region,
wherein the channel comprises a multi-bridge channel structure, and
wherein the first gate line comprises a gate-all-around structure.

16. The integrated circuit of claim 12, wherein, a width of the first cell in the second direction is defined as a first width,
the number n of the front-side metal lines is based on the first width or the first pitch,
the number m of the back-side metal lines is based on the first width or the second pitch, and
the number n of the front-side metal lines is greater than or equal to the number m of the back-side metal lines.

17. An integrated circuit comprising:
a back-side wire layer comprising back-side metal lines extending in a first direction, the back-side metal lines being spaced apart from each other in a second direction perpendicular to the first direction;
a field effect transistor above the back-side wire layer; and
a front-side wire layer above the field effect transistor, wherein the front-side wire layer comprises front-side metal lines that extend in the first direction and are spaced apart from each other in the second direction,
wherein a first front-side power line and a second front-side power line of the front-side metal lines are aligned with cell boundaries of a cell in the second direction, wherein the first front-side power line and the second front-side power line are configured to receive power,
wherein a first back-side power line and a second back-side power line of the back-side metal lines are aligned with the cell boundaries of the cell in the second direction, wherein the first back-side power line and the second back-side power line are configured to receive power,
wherein n front-side metal lines are arranged in the cell in the second direction at a first pitch, wherein n is an integer greater than or equal to 1, and
wherein m back-side metal lines are arranged in the cell in the second direction at a second pitch, wherein m is an integer greater than or equal to 1.

18. The integrated circuit of claim 17, comprising:
gate lines extending in the second direction and arranged in the first direction at a third pitch; and
a power tap cell comprising a contact configured to connect the first front-side power line and the second front-side power line to an active region and a back-side contact configured to connect the first back-side power line and the second back-side power line to the active region,
wherein the power tap cell has a width equal to a width of one or more cells in the first direction and a length equal to or greater than a length of the third pitch in the second direction.

19. The integrated circuit of claim 18,
wherein the first front-side power line or the second front-side power line is located between two cells that are adjacent to each other in the second direction,
wherein the contact is connected in common to active regions in the two adjacent cells,
wherein the contact is connected to the first front-side power line or the second front-side power line through a via, and
wherein the back-side contact is connected to the first back-side power line or the second back-side power line through a back-side via.

20. The integrated circuit of claim 17, wherein, a width of the cell in the second direction being defined as a first width,
the number n of the front-side metal lines is based on the first width or the first pitch,
the number m of the back-side metal lines is based on the first width or the second pitch, and
the number n of the front-side metal lines is greater than or equal to the number m of the back-side metal lines.
